(19) United States
(12) Patent Application Publication
(10) Pub. No.: US 2025/0357177 A1
(43) Pub. Date: Nov. 20, 2025

(54) DEVICE FOR CONVEYING A WAFER-SHAPED ARTICLE

(71) Applicant: LAM RESEARCH AG, Villach (AT)

(72) Inventor: Roland HABERLE, Villach (AT)

(21) Appl. No.: 19/120,151

(22) PCT Filed: Oct. 10, 2023
(86) PCT No.: PCT/EP2023/078042

§ 371 Date: Apr. 10, 2025

(30) Foreign Application Priority Data
Oct. 4, 2022 (GB) 2215215.1

(51) Int. Cl. H01L 21/683; B25J 11/00; H01L 21/687

(52) U.S. Cl. CPC H01L 21/6838; H01L 21/68707; B25J 11/0095

(57) ABSTRACT

Device for conveying a wafer-shaped article, comprising: a support having a support surface; one or more gas channels in the support having one or more outlets in the support surface; and one or more grooves in the support surface for receiving at least part of an end effector for supporting a wafer-shaped article.

### FIELD OF THE INVENTION

The present invention relates to a device for conveying a wafer-shaped article, such as a semiconductor wafer.

### BACKGROUND

In semiconductor device fabrication, a plurality of different processes are typically performed on a semiconductor wafer to fabricate a semiconductor device on the wafer. These processes typically include etching a layer of material that has previously been deposited on the surface of the wafer to remove some of the material. This is typically achieved by dispensing an etching chemical onto the surface of the wafer to etch the layer of material on the surface of the wafer. The wafer may be spun during the etching process, in a so-called spin etching process.

When performing such an etching process, the wafer to be processed is typically removed from a wafer cassette, such as a Front Opening Unified Pod (FOUP). The wafer to be processed is then typically placed on a wafer support, for example a rotatable chuck, with the side of the wafer having the layer of material to be etched facing upwards. Then, an etching chemical is dispensed onto the layer of material on the surface of the wafer facing upwards to etch the layer of material. The opposite side of the wafer is typically prevented from coming into contact with the etching chemical, so that the other side of the wafer is protected from the etching chemical.

After the etching process has been performed, the surface of the wafer facing upwards may subsequently be cleaned, for example by dispensing a cleaning or rinse liquid onto the surface of the wafer. Again, the wafer may be spun during the cleaning process, in a so-called spin cleaning process.

Afterwards, the wafer may then be picked up off the wafer support and transported to the same or a different wafer cassette, or to a further processing apparatus for further processing.

In an apparatus previously used by the applicant for performing such an etching process, a wafer is removed from a wafer cassette using an end effector of a robotic arm. The end effector is typically a Bernoulli type end effector or Bernoulli end effector, which makes use of the Bernoulli principle or effect to support the wafer in a non-contact manner. Such an end effector typically has a plurality of gas outlets on a support surface of the end effector that are configured to supply gas so as to support the wafer in a non-contact manner according to the Bernoulli principle or effect.

In particular, a gas cushion is formed between the support surface of the end effector and the wafer, wherein the gas flow is such that a low pressure (or lower pressure or reduced pressure) is formed, at least in sections, between the support surface of the end effector and the wafer. This means that the wafer is sucked towards the support surface of the end effector by the low pressure so that the wafer is held by the end effector, but is prevented from coming into contact with the support surface of the end effector by the cushion of gas. The wafer is therefore supported on a cushion of gas and held spaced apart from the support surface of the end effector.

Typically, such an end effector is positioned beneath the wafer and is used to support the wafer from beneath.

Such an end effector is typically thin and plate-like or blade-like, so that the end effector can be inserted between different wafers held in a stack in a wafer cassette.

The end effector may be similar to the tool described in U.S. Pat. No. 5,967,578, for example, the entire contents of which are incorporated herein by reference.

In the apparatus previously used by the applicant, the wafer supported by the end effector is transported by the robotic arm to a further wafer conveying device that is used to subsequently convey the wafer from the end effector to the wafer support for processing.

The wafer conveying device may be similar to the conveying device described in U.S. Pat. No. 6,152,507, for example, the entire contents of which are incorporated herein by reference.

The wafer conveying device is configured to support the wafer from above according to the Bernoulli principle or effect. The wafer conveying device may therefore be a so-called Bernoulli gripper or Bernoulli grip, for example.

A schematic illustration of such a wafer conveying device is illustrated in FIG. 9A, for example. As illustrated in FIG. 9A, the wafer conveying device comprises a support 1 having a plane surface 3 on its lower or bottom side. In the support 1 there is formed a gas channel 5 which, in running towards the plane surface 3 in an outwardly slanting manner, terminates at one of its ends in a gas outlet opening in the plane surface 3. The gas channel 5 is connectable to a gas supply pipe 7 at its other end, for supplying gas through the gas channel 5 to the plane surface 3.

The gas channel 5 is an annular gap formed between an insert portion of the support 1 and a main body portion of the support 1. The gas channel 5 is therefore an annular gas channel.

The gas channel 5 is configured such that gas supplied from the gas channel 5 to the plane surface 3 supports a wafer 9 in a non-contact manner beneath the plane surface 3 of the support 1 according to the Bernoulli principle or effect.

In particular, a gas cushion is formed between the plane surface 3 of the wafer conveying device and the wafer 9, wherein the gas flow through the gas channel 5 is such that a low pressure (or lower pressure or reduced pressure) is formed, at least in sections, between the plane surface 3 and the wafer 9. In particular, a low pressure is formed at least in a central region of the plane surface 3 inside of the annular gas channel 5. This means that the wafer 9 is sucked towards the plane surface 3 by the low pressure so that the wafer 9 is held by the wafer conveying device, but is prevented from coming into contact with the plane surface 3 by the cushion of gas. The wafer 9 is therefore supported on a cushion of gas and held spaced apart from the plane surface 3 beneath the plane surface 3.

To transfer the wafer 9 from the end effector 2 to the wafer conveying device, the wafer conveying device is positioned above the wafer 9 while the wafer 9 is supported from beneath by the end effector. Then, by providing gas through the gas channel 5 of the wafer conveying device, the wafer 9 is sucked upwards towards the plane surface 3 of the support 1 due to the low pressure (or lower pressure or reduced pressure) caused by the flow of gas through the gas channel 5, but is prevented from coming into contact with the plane surface 3 by the flow of gas. Any supply of gas from the end effector 2 may be stopped at the same time, to assist transfer of the wafer 9 from the end effector 2 to the wafer conveying device.

The wafer conveying device is then used to transport the wafer 9 to the wafer support, for example a rotary chuck, and to lower the wafer 9 onto the wafer support for subsequent processing of the wafer 9.

For example, the support 1 may be attached to a transport device or transport mechanism or manipulator, for example a robotic arm, for moving the support 1 and therefore the wafer held by the support 1.

As shown in FIG. 9A, the wafer conveying device further comprises a plurality of guiding arms 11 that are disposed adjacent to the gas outlet opening outside of the gas outlet opening. The plurality of guiding arms 11 project beyond the plane surface 3 of the support 1 and are adjustable radially with respect to the plain surface 3.

The plurality of guiding arms 11 are configured to restrict or limit lateral movement of the wafer 9 that is supported beneath the plane surface 3 relative to the plane surface 3. In particular, the plurality of guiding arms are configured to contact a circumferential edge of the wafer 9 if the wafer 9 is displaced laterally relative to the plane surface 3, to restrict or limit lateral movement of the wafer 9 relative to the plane surface 3. Therefore, the guiding arms 11 do not grip the wafer 9, but instead form adjustable circumferential alignment surfaces, alignment lines or alignment points for the wafer 9.

Subsequently, after the wafer has been processed, the wafer can then be picked up from the wafer support from above using the wafer conveying device and transported back to the end effector. The end effector can be positioned beneath the wafer and the wafer can then be passed from the wafer conveying device to the end effector, so that it can then be transported by the end effector to the same or a different wafer cassette, or to a further processing apparatus for further processing.

The present inventor has realised that a possible downside of this existing arrangement is that it is difficult to use the existing arrangement to perform processing of both a frontside and a backside of a wafer. In particular, transfer of the wafer between the end effector and the wafer conveying device is only possible in a specific configuration where the end effector is beneath the wafer and the wafer conveying device is above the wafer (i.e. the wafer is located between the end effector and the wafer conveying device).

For example, in the arrangement described above the end effector 2 can pick up a wafer from a wafer cassette with the end effector positioned beneath the wafer and a first side of the wafer facing upwards away from the end effector. The end effector 2 can then position the wafer beneath the support 1 of the wafer conveying device with the first side of the wafer facing upwards towards the support 1, and support of the wafer can be transferred from the end effector to the support 1. Then, the wafer conveying device can convey the wafer to the wafer support, for example a rotary chuck, and lower the wafer onto the wafer support, with the first side of the wafer facing upwards away from the wafer support. The first side of the wafer can then be processed.

However, with such an arrangement it is not possible for a second side of the wafer that is opposite to the first side to be processed, since the wafer cannot be positioned on the wafer support with the second side of the wafer facing upwards away from the wafer support.

Alternatively, if the wafer 9 is picked by the end effector 2 from above (FIG. 9B) with the first side facing the end effector 9, the second side would face the conveying device and thus only the second side would be processed. Picking the wafer in this manner may be required if the wafer is very thin and/or warped, when the end effector is a Bernoulli end effector. So, the way the wafer is picked from the cassette results in how it can be processed.

The present invention has been devised in light of the above considerations.

### SUMMARY OF THE INVENTION

According to a first aspect of the present invention there is provided a device for conveying a wafer-shaped article, the device comprising: a support having a support surface; one or more gas channels in the support having one or more outlets in the support surface; and one or more grooves in the support surface for receiving at least part of an end effector for supporting a wafer-shaped article.

According to the present invention, at least part of an end effector for supporting a wafer-shaped article can be received in the one or more grooves in the support surface. Therefore, in a first arrangement, at least part of an end effector that is supporting a wafer-shaped article may be inserted into the one or more grooves in the support surface, with the end effector positioned between the support and the wafer-shaped article. For example, the end effector may be moved perpendicularly to the support surface to insert at least part of the end effector into the one or more grooves in the support surface, and/or the end effector may be moved parallel to the support surface (for example laterally) to insert at least part of the end effector into the one or more grooves in the support surface. Support of the wafer-shaped article may then be transferred from the end effector to the support, and the end effector may then be laterally withdrawn from the one or more grooves in the support surface while the wafer is supported by the support.

In addition, in a second arrangement, an end effector that is supporting a wafer-shaped article may be positioned with the wafer-shaped article between the end effector and the support. Support of the wafer-shaped article may then be transferred from the end effector to the support and the end effector and/or the support may then be moved away.

This may facilitate positioning the wafer-shaped article on the support with either a first main face of the wafer-shaped article facing away from the support or a second main face of the wafer-shaped article facing away from the support. This may facilitate subsequently positioning the wafer-shaped article on a wafer support (such as a rotary chuck) of a processing apparatus with either the first main side of the wafer-shaped article facing upwards for processing, or the second main side of the wafer-shaped article facing upwards for processing.

This may be advantageous, for example, where it is desired to perform processing of both a front side and a back side of the wafer, and therefore it is necessary to consecutively expose both sides of the wafer-shaped article in one or more processing devices for processing.

The device according to the first aspect of the present invention may have any one, or, where compatible, any combination of the following optional features.

The device may instead be referred to as an apparatus.

The device may be a conveying device, or a transporting device, or a moving device.

The device may be a wafer conveying device.

Conveying a wafer-shaped article may mean moving or transporting the wafer-shaped article.

The wafer-shaped article may be a wafer, for example a semiconductor wafer such as a silicon wafer.

The wafer-shaped article may be disk-like or disk-shaped.

The wafer-shaped article may be circular or substantially circular.

The support may be a part of the device that faces a wafer-shaped article being conveyed by the device.

The support may be a part of the device that supports a wafer-shaped article being conveyed by the device.

The support may be for supporting the wafer-shaped article, or configured or adapted to support the wafer-shaped article.

The support may comprise a single part, or multiple parts.

The support surface may be a surface of the support that faces a wafer-shaped article being conveyed by the device.

The support surface may be for supporting the wafer-shaped article, or configured or adapted to support the wafer-shaped article.

The support surface may be for supporting the wafer-shaped article, or configured or adapted to support the wafer-shaped article, in a non-contact manner.

The support surface may be planar, plane, or flat, or substantially planar, plane or flat.

The support surface may be a bottom surface or lower surface of the support.

The support surface may be a bottom surface or lower surface of the device.

The one or more gas channels may comprise one or more nozzles, bores, tubes, pipes, or passages.

The one or more gas channels may comprise a slit or slot or gap.

The one or more gas channels may be for conveying or transporting or supplying gas to the one or more outlets, or may be configured to convey or transport or supply gas to the one or more outlets.

The one or more gas channels being in the support may mean that the one or more gas channels are inside the support, or housed in the support, or enclosed by the support.

Each of the one or more gas channels may have a respective outlet in the support surface.

The one or more outlets may be one or more gas outlets.

The one or more outlets may be one or more openings or holes in the support surface.

The one or more outlets may comprise an elongate outlet, for example an annular outlet.

An opposite end (opposite to the outlet) of each of the one or more gas channels may be connected to, or configured to be connected to, a gas supply arrangement, or a gas supply, for example a gas supply pipe that is configured to supply gas to the one or more gas channels. The connection may be a direct connection or an indirect connection via another part such as an additional pipe or chamber.

The support may comprise the gas supply arrangement, or gas supply.

The device may comprise or be connected or connectable to a gas supply or gas source for supplying gas to the one or more gas channels. For example, the gas supply or gas source may comprise a tank or container of gas, for example pressurised gas.

The device may comprise or be connected or connectable to a source of gas, for example a source of compressed gas.

The one or more grooves may comprise one or more trenches, or troughs, or channels, or recesses, or cut-outs, or depressions, or indentations.

The one or more grooves may be adapted or configured to receive at least part of an end effector for supporting a wafer-shaped article.

The one or more grooves may be for receiving at least part of a distal end of the end effector.

The one or more grooves may be for receiving a distal end of the end effector.

The one or more grooves may be for receiving at least part of a support part of the end effector that is configured to support a wafer-shaped article. The one or more grooves may be for receiving a support part of the end effector that is configured to support a wafer-shaped article.

The one or more grooves may be adapted or configured to receive at least part of a support part of the end effector that is configured to support a wafer-shaped article. The one or more grooves may be adapted or configured to receive a support part of the end effector that is configured to support a wafer-shaped article.

The at least part of the end effector may be or comprise a distal end of the end effector.

The one or more grooves may be configured to receive a whole thickness of at least part of an end effector, for example a whole thickness of a distal end of the end effector. This may be achieved by a depth of the one or more grooves being the same as, or greater than, a thickness of the part of the end effector.

The one or more grooves may be for receiving one or more forks or fingers or prongs or blades of the end effector.

The one or more grooves may be for receiving a forked end of the end effector.

At least part of the end effector may be insertable into the one or more grooves by the end effector being moved perpendicularly to the support surface.

In addition, or alternatively, at least part of the end effector may be insertable into the one or more grooves by the end effector being moved parallel to the support surface, for example by the end effector being moved laterally or sideways relative to the support surface or support.

The one or more grooves may be adapted or configured to receive at least part of the end effector while a wafer-shaped article is being supported or conveyed by the device.

The one or more grooves may be adapted or configured so that at least part of the end effector can be laterally inserted into the one or more grooves while a wafer-shaped article is being supported or conveyed by the device.

The one or more grooves may be adapted or configured so that at least part of the end effector can be laterally withdrawn from the one or more grooves while a wafer-shaped article is being supported or conveyed by the device.

The device may further comprise a plurality of limiting elements configured to limit lateral movement of a wafer-shaped article being conveyed by the device relative to the support surface.

The support may comprise the plurality of limiting elements.

The limiting elements may comprise arms, for example guiding arms, or pins, or protrusions, or members, or parts.

The limiting elements may be at the ends of respective arms, which may extend in a radial direction of the support. The arms may be linearly extendable arms.

The limiting elements may be positioned around or outside of a periphery or circumference or outer edge of the support surface.

The limiting elements may project beyond the support surface from the device.

Positions of the limiting elements relative to the support surface may be adjustable. For example, the positions of the limiting elements may be radially adjustable with respect to the support surface.

The plurality of limiting elements may be configured to contact a circumferential edge of the wafer-shaped article being conveyed by the device if the wafer-shaped article is displaced laterally relative to the support surface.

The plurality of limiting elements may form circumferential alignment surfaces, alignment lines, or alignment points, which may be adjustable in position, for example radially adjustable in position.

There may be three or more of the limiting elements, for example.

The one or more gas channels may be configured to supply gas (from the one or more outlets) to support a wafer-shaped article according to the Bernoulli principle or effect.

The one or more gas channels may be configured to supply gas (from the one or more outlets) to support a wafer-shaped article in a non-contact manner.

The one or more gas channels may be configured to supply gas (from the one or more outlets) such that a gas cushion is formed between the support surface of the device and a wafer-shaped article.

The one or more gas channels may be configured to supply gas (from the one or more outlets) such that a low pressure (or lower pressure or reduced pressure) is formed, at least in sections, between the support surface and the wafer-shaped article. For example, a low pressure (or reduced pressure) may be formed at least in a central region of the support surface. Therefore, the wafer-shaped article may be sucked towards the support surface because of the low pressure.

The one or more gas channels may be configured to supply gas (from the one or more outlets) such that a wafer-shaped article is supported on a cushion of gas and held spaced apart from the support surface, for example beneath the support surface.

The device may comprise a plurality of the gas channels in the support, each having a respective outlet in the support surface.

The plurality of outlets may be arranged in a circularly symmetric, or substantially circularly symmetric, arrangement on the support surface.

Each of the plurality of outlets may be arranged in one or more arcs or part or segment of a circle on the support surface.

The one or more gas channels may each be angled or slanted outwards relative to the support surface.

The one or more gas channels may each be angled or slanted outwards relative to the support surface in running towards the support surface.

The one or more gas channels may each be angled or slanted outwards away from a centre of the support surface.

The one or more gas channels may each be angled or slanted outwards away from a centre of the support surface in running towards the support surface.

The one or more gas channels may each be angled or slanted radially outwards relative to the support surface.

The one or more gas channels may each be angled or slanted radially outwards away from a centre of the support surface.

The one or more gas channels may each be angled or slanted so that gas exits the one or more outlets in an outward direction relative to the support surface (i.e. away from a centre of the support surface) at an angle to the support surface.

The angle may be greater than 0° and less than 90° to the support surface.

The angle may be an acute angle.

The one or more gas channels may each be at an angle of >0° and <90° to the support surface.

The one or more grooves may each be linear or substantially linear.

The one or more grooves may each extend linearly or substantially linearly in the plane of the support surface or parallel to the plane of the support surface.

The device may comprise two or more of the grooves.

Each of the one or more grooves may extend to an edge of the support surface, for example so that the end effector can be laterally inserted into the one or more grooves from the edge of the support surface or support and/or so that the end effector can be laterally withdrawn from the one or more grooves from the edge of the support surface or support.

Therefore, the end effector may be moved laterally relative to the device or support surface of the device (i.e. parallel to the support surface) so that at least part of the end effector (for example a distal end of the end effector) is received in the one or more grooves and/or so that the end effector is withdrawn from the one or more grooves.

As mentioned above, the one or more grooves may be adapted or configured to receive at least part of the end effector while a wafer-shaped article is being supported or conveyed by the device. Therefore, the end effector can be inserted between the device and the wafer-shaped article while the wafer-shaped article is being supported or conveyed by the device.

The device may comprise one or more openings or holes or cut-outs in the one or more grooves.

The device may comprise one or more openings or holes or cut-outs in the support surface in the one or more grooves.

The one or more openings or holes or cut-outs may be configured to allow gas that enters the one or more grooves to exit the one or more grooves through the one or more openings or holes or cut-outs. This may prevent the pressure in the one or more grooves from being increased.

The one or more openings or holes or cut outs may be configured to allow gas to exit the one or more grooves through the support surface.

The one or more openings or holes or cut outs are larger than the one or more outlets of the one or more gas channels.

The one or more openings or holes or cut-outs may extend from one side of the support to an opposite side of the support.

The device may comprise a gas distribution chamber in the support, wherein each of the one or more gas channels is connected to the gas distribution chamber.

The device may comprise a gas supply pipe connected to the gas distribution chamber for supplying gas to the gas distribution chamber.

The support surface may be on an underside of the device when the device is used to convey a wafer-shaped article.

The support surface may be a bottom or lower surface of the device when the device is used to convey a wafer-shaped article.

The device may be for conveying a wafer-shaped article with a diameter of 300 mm, for example.

The device may be configured to support a wafer-shaped article from above the wafer-shaped article.

In addition, or alternatively, the device may be configured to support a wafer-shaped article from below the wafer-shaped article.

The device may further comprise a transport device, or transport mechanism, or manipulator, for moving the support 1. For example, the device may comprise a robotic arm or other actuator for moving the support.

The device may comprise a rotation mechanism or flipping mechanism for flipping the support. Flipping the support means turning the support upside down, or turning the support over, for example so that a surface of the support that previously faced upwards then faces downwards.

The rotation mechanism or flipping mechanism may alternatively be referred to as a rotation actuator or flipping actuator or rotation module or flipping module.

This may facilitate positioning the wafer-shaped article on the support from the end effector with either a first main face of the wafer-shaped article facing away from the support or a second main face of the wafer-shaped article facing away from the support.

Alternatively, or in addition, the end effector may be rotatable or flipable so as to flip the end effector.

This may facilitate positioning the wafer-shaped article on the support from the end effector with either a first main face of the wafer-shaped article facing away from the support or a second main face of the wafer-shaped article facing away from the support.

The device may comprise two of the supports arranged with their support surfaces facing in opposite directions, or substantially opposite directions. For example, the two supports may be arranged in a unit with one support positioned above the other support and with the support surfaces of the supports facing in opposite directions.

The device may comprise a rotation mechanism, actuator or module or a flipping mechanism, actuator or module for flipping the unit.

An end effector supporting a wafer-shaped article from above may be used to position the wafer-shaped article on the upper one of the supports with the wafer-shaped article located between the end effector and the upper one of the supports.

Alternatively, the end effector supporting the wafer-shaped article from above may be used to position the wafer-shaped article on the lower one of the supports with the end effector located between the wafer-shaped article and the lower one of the supports.

This may facilitate positioning the wafer-shaped article on the supports from the end effector with either a first main face of the wafer-shaped article facing away from the support or a second main face of the wafer-shaped article facing away from the support.

According to a second aspect of the present invention there is provided a plate for use in a device for conveying a wafer-shaped article, comprising: a support surface; one or more gas channels in the plate having one or more outlets in the support surface; and one or more grooves in the support surface for receiving at least part of an end effector for supporting a wafer-shaped article.

The second aspect of the present invention may have any of the features of the first aspect of the present invention described above, unless incompatible.

The plate of the second aspect of the present invention may have any of the features of the support of the first aspect of the present invention, unless incompatible.

The support surface of the second aspect of the present invention may have any of the features of the support surface of the first aspect of the present invention, unless incompatible.

The one or more gas channels of the second aspect of the present invention may have any of the features of the one or more gas channels of the first aspect of the present invention, unless incompatible.

The one or more outlets of the second aspect of the present invention may have any of the features of the one or more outlets of the first aspect of the present invention, unless incompatible.

The one or more grooves of the second aspect of the present invention may have any of the features of the one or more grooves of the first aspect of the present invention, unless incompatible.

The plate of the second aspect of the present invention may correspond to, or be used as, the support, or part of the support, of the first aspect of the present invention.

The plate may be a Bernoulli plate, or a Bernoulli grip plate, or a Bernoulli gripper, or a Bernoulli grip.

According to a third aspect of the present invention there is provided a support for use in a device for conveying a wafer-shaped article, comprising: a support surface; one or more gas channels in the support having one or more outlets in the support surface; and one or more grooves in the support surface for receiving at least part of an end effector for supporting a wafer-shaped article.

The support of the third aspect of the present invention may have any of the features of the support of the first aspect of the present invention, unless incompatible.

According to a fourth aspect of the present invention there is provided a device for conveying a wafer-shaped article, comprising a plate according to the second aspect of the present invention or a support according to the third aspect of the present invention.

The fourth aspect of the present invention may have any of the features of the first, second or third aspects of the present invention, unless incompatible.

According to a fifth aspect of the present invention there is provided an apparatus comprising: a device according to the first or fourth aspect of the present invention; and a robotic arm having an end effector; wherein the end effector is configured to be at least partly insertable into the one or more grooves in the support surface of the device.

The apparatus may further comprise a wafer processing apparatus or wafer processing device.

The apparatus may comprise a spin etching and/or a spin cleaning apparatus.

The end effector may be blade-like, or plate-like.

The end effector may have one or more forks or fingers or prongs or blades, for example two forks or fingers or prongs or blades.

The end effector may have a forked end.

The end effector may have a planar or flat, or substantially planar or flat, support surface for supporting a wafer-shaped article.

The end effector may have a support part that is configured or adapted to support a wafer-shaped article.

The end effector may be a Bernoulli type end effector or Bernoulli end effector.

The end effector may be configured to support a wafer-shaped article in a non-contact manner according to the Bernoulli principle or effect.

The end effector may comprise a support surface having one or more gas outlets.

The one or more gas outlets may be configured to supply gas so as to support a wafer-shaped article in a non-contact manner according to the Bernoulli principle or effect.

The one or more gas outlets may be configured to output gas from the support surface in an outwards direction relative to the support surface and at an angle to the support surface. The angle may be greater than 0° and less than 90°.

The one or more gas outlets may be configured to form a gas cushion between the support surface of the end effector and the wafer-shaped article, so that a low pressure (or lower pressure or reduced pressure) is formed, at least in sections, between the support surface and the wafer-shaped article. This means that the wafer-shaped article is sucked towards the support surface of the end effector by the low pressure so that the wafer-shaped article is held by the end effector, but is prevented from coming into contact with the support surface of the end effector by the cushion of gas. The wafer-shaped article is therefore supported on a cushion of gas and held spaced apart from the support surface of the end effector.

The end effector may be configured to be positioned beneath the wafer-shaped article and to support the wafer-shaped article from beneath.

The end effector may additionally, or alternatively be configured to be positioned above the wafer-shaped article and to support the wafer-shaped article from above.

The end effector may be configured to be inserted between different wafers held in a stack in a wafer cassette.

The end effector may be configured to be at least partly received in the one or more grooves while a wafer-shaped article is being supported or conveyed by the device.

The end effector may be configured to be laterally inserted into the one or more grooves.

The invention includes the combination of the aspects and preferred features described except where such a combination is clearly impermissible or expressly avoided.

The apparatus may further comprise a support for supporting a wafer cassette.

The robotic arm may be configured to transport a wafer from the wafer cassette to the device using the end effector.

The device may be configured to transport the wafer, that has been transported to the device by the robotic arm, to the wafer processing apparatus for processing.

Transferring support of the wafer-shaped article from the end effector to the support may comprise stopping a flow of gas from one or more openings of the end effector and starting a flow of gas from one or more openings of the support.

The gas may be Nitrogen gas.

### SUMMARY OF THE FIGURES

Embodiments and experiments illustrating the principles of the invention will now be discussed with reference to the accompanying figures in which:

FIG. 1 is a schematic illustration of a first main side of a device according to an embodiment of the present invention.

FIG. 2 is a schematic illustration of a perspective view of the first main side of the device of FIG. 1.

FIG. 3 is a schematic illustration of a perspective view of a second main side of the device of FIG. 1.

FIG. 4 is a schematic illustration of a device according to an embodiment of the present invention.

FIG. 5 is a schematic illustration of an end effector that can be used in embodiments of the present invention.

FIG. 6 is a schematic view of a device according to an embodiment of the present invention.

FIG. 7 is an enlarged schematic view of part of the device of FIG. 6 with a wafer present.

FIG. 8 is a schematic view of an apparatus according to an embodiment of the present invention.

FIG. 9A and FIG. 9B are schematic illustrations of a known wafer conveying device.

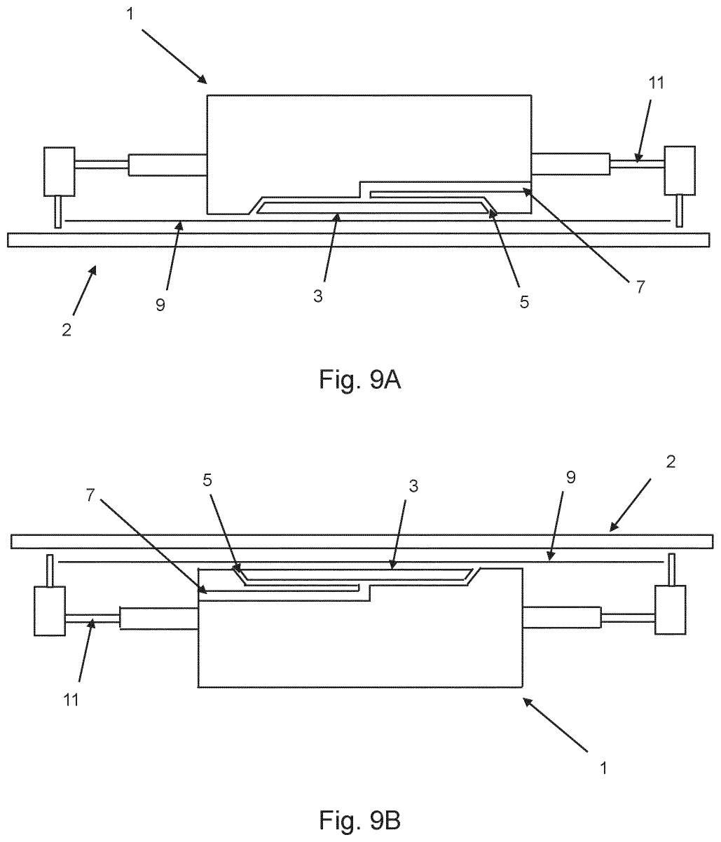

### DETAILED DESCRIPTION OF THE INVENTION

Aspects and embodiments of the present invention will now be discussed with reference to the accompanying figures. Further aspects and embodiments will be apparent to those skilled in the art. All documents mentioned in this text are incorporated herein by reference.

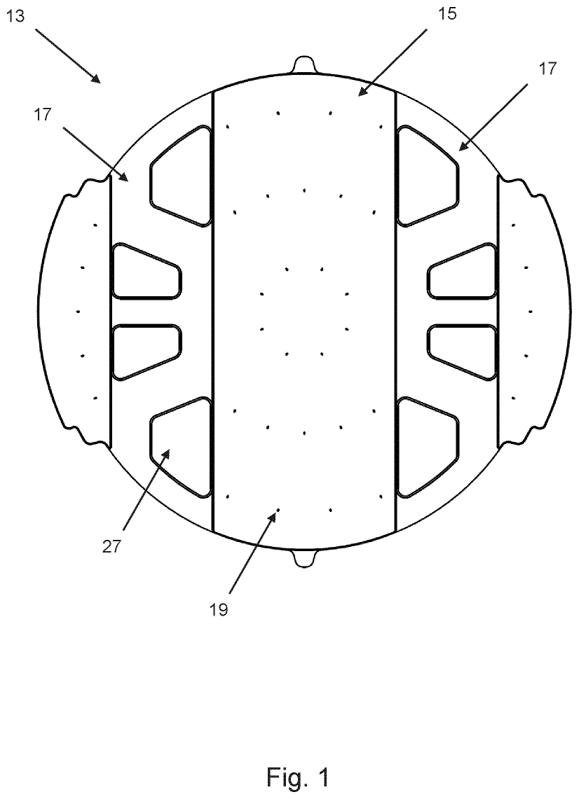

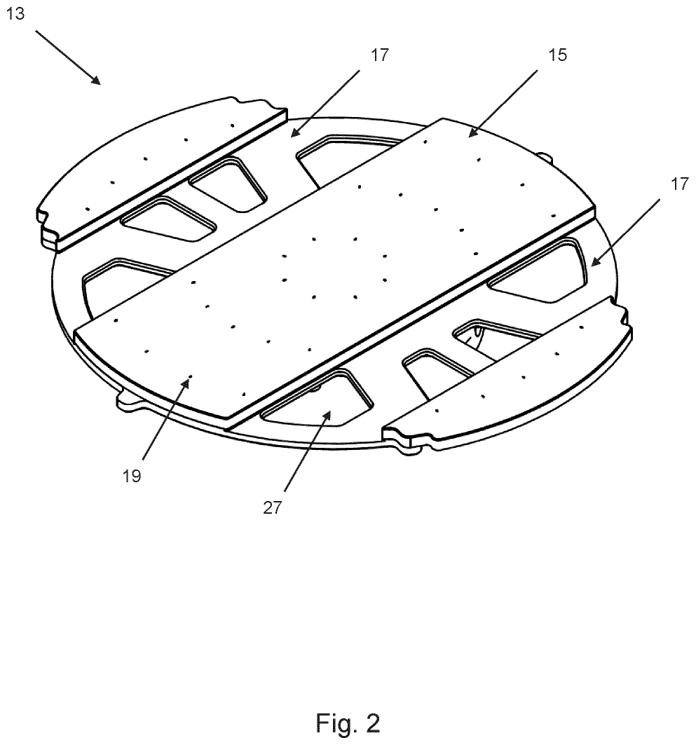

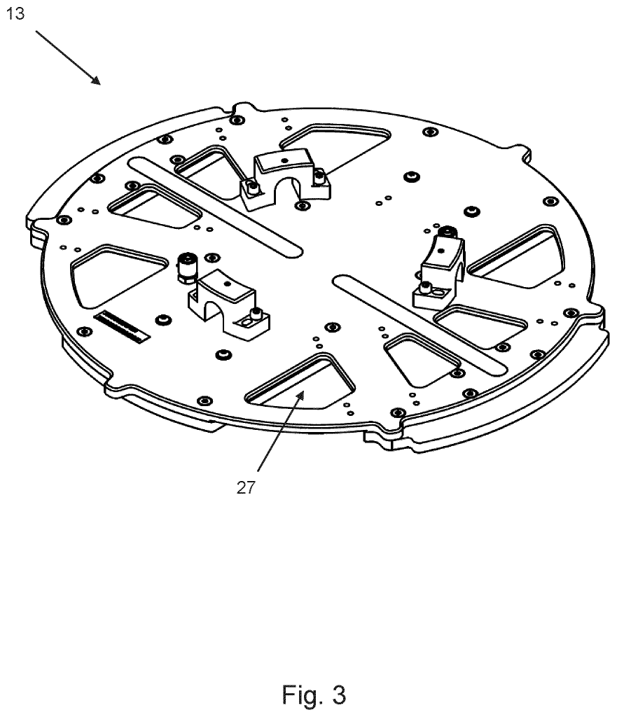

FIGS. 1 to 3 are schematic illustrations of a plate (or support) that can be used in a wafer conveying device for conveying a wafer. FIG. 1 is a schematic illustration of a first main side of the plate, FIG. 2 is a schematic illustration of a perspective view of the first main side of the plate, and FIG. 3 is a schematic illustration of a perspective view of a second main side of the plate.

As illustrated in FIGS. 1 to 3, the plate 13 is substantially circular. The plate may have a diameter of between 250 mm and 300 mm, for example.

The plate 13 comprises a support surface 15 that is configured to face a wafer such as a semiconductor wafer. The support surface 15 is configured to support a wafer in a non-contact manner as described below.

Two channels 17 for receiving at least part of an end effector are formed in the support surface 15. The two channels 17 each extend linearly in the plane of the support surface 15, or parallel to the plane of the support surface 15, from one side or edge of the support surface 15 to another side or edge of the support surface 15. The two channels 17 therefore span the support surface 15.

The two channels 17 are configured to receive two forks, fingers, prongs or blades of an end effector that is used to support the wafer. In particular, the two forks, fingers, prongs or blades of the end effector can be at least partly inserted into the two channels 17 by moving the end effector perpendicularly to the support surface 15 and/or by moving the end effector parallel to the support surface 15. Furthermore, the two channels 17 are configured so that the two forks, fingers, prongs or blades of the end effector can be laterally withdrawn from the support 13 from the side of the support 13 while the wafer is being supported by the plate 13.

The depth of the two channels 17 is configured so that the two forks, fingers, prongs or blades of the end effector can be received in the two channels 17 while a wafer is being supported or conveyed using the plate 13. For example, the two channels 17 may have a depth that is greater than a thickness of the two forks, fingers, prongs or blades of the end effector. For example, the two channels 17 may have a depth greater than or equal to 1 mm and less than or equal to 5 mm.

In addition, the plate 13 comprises a plurality of gas channels having openings 19 in the support surface 15. The gas channels are configured to supply gas through the openings 19 so as to support a wafer above or beneath the support surface 15 in a non-contact manner according to the Bernoulli principle or effect.

In particular, when gas is supplied through the openings 19, a gas cushion is formed between the support surface 15 and a wafer opposite to the support surface 15 (for example below the support surface 15), wherein the gas flow through the openings 19 is such that a low pressure (or lower pressure or reduced pressure) is formed, at least in sections, between the support surface 15 and the wafer. In particular, a low pressure may be formed at least in a central region of the support surface 15. This means that the wafer is sucked towards the support surface 15 by the low pressure so that the wafer is held by the plate 13, but is prevented from coming into contact with the support surface 15 by the cushion of gas. The wafer is therefore supported on a cushion of gas and held spaced apart from the support surface 15, for example beneath the support surface 15.

The plurality of gas channels are each angled or slanted outwards relative to the support surface 15 in running towards the support surface 15. Therefore, gas exits each of the plurality of outlets 19 in an outward direction relative to the support surface 15 (i.e. away from a centre of the support surface 15) at an angle to the support surface 15. The angle is >0° and <90° to the support surface 15, i.e. an acute angle.

As illustrated in FIGS. 1 and 2, each of the plurality of outlets 19 are arranged in one or more arcs or parts or segments of a circle on the support surface 15. Furthermore, the plurality of outlets 19 are arranged in a circularly symmetric, or substantially circularly symmetric, arrangement on the support surface 15.

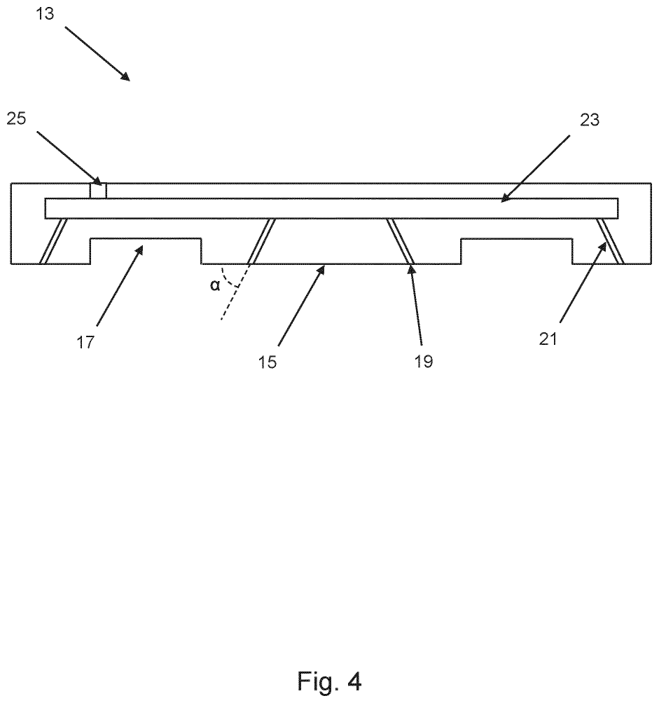

FIG. 4 is a schematic illustration of a device according to an embodiment of the present invention, for example the plate 13 of the embodiment illustrated in FIGS. 1 to 3. As shown in FIG. 4, the plurality of gas channels 21 in the plate 13 are each angled outwards away from a centre of the support surface 15 in running towards the support surface 15. Therefore, gas exits each of the gas channels 21 from the respective outlet 19 in an outwards direction relative to a centre of the support surface 15 at an angle a that is >0° and <90° to the support surface 15.

As illustrated in FIG. 4, opposite ends of the gas channels 21 to the outlets 19 are connected to a gas distribution chamber 23 in the plate 13. Therefore, gas can be supplied to each of the gas channels 21 from the gas distribution chamber 23. Furthermore, the plate 13 comprises a gas inlet 25 connected to the gas distribution chamber 23 through which gas can be supplied from outside of the plate 13 to the gas distribution chamber 23. Of course, the gas distribution chamber 23 and gas inlet 25 are merely one example of an arrangement for suppling gas to the gas channels 21 and alternative arrangements are possible and within the scope of the present invention. For example, a gas supply pipe may be directly connected to each of the gas channels 21. Furthermore, the location of the gas inlet 25 may be different to that illustrated in FIG. 4.

As shown in FIGS. 1 to 3, the plate 13 comprises a plurality of cut outs 27 in the grooves 17. The cut outs 27 provide flow paths through the whole thickness of the plate 13 in the grooves 17. In particular, the cut outs 27 provide holes or openings that extend from one main side or main face of the plate 13 to the other main side or main face of the plate 13. These cut outs 27 allow gas that is output from the outlets 19 of the gas channels and that enters the grooves 17 to escape from the grooves 17. Otherwise, the pressure in the grooves 17 may increase and prevent the wafer from being correctly held by a low pressure (or lower pressure or reduced pressure) according to the Bernoulli principle or effect.

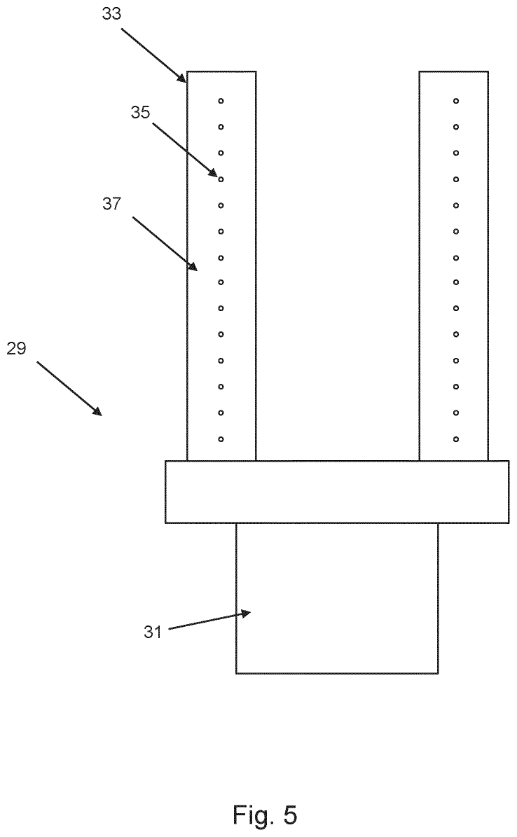

FIG. 5 is a schematic illustration of an end effector that can be used in embodiments of the present invention. As illustrated in FIG. 5, the end effector 29 comprises a body part 31 and two forks, fingers, prongs or blades 33 that extend from the body part 31. The end effector 31 may be plate-like or blade-like.

The body part 31 may be configured (for example shaped) to be received by the distal end of a robotic arm. Therefore, the end effector 29 may be connected or connectable to the distal end of a robotic art.

The forks, fingers, prongs or blades 33 of the end effector 29 provide a support part of the end effector 29 for supporting a wafer. In this embodiment the end effector 29 is a Bernoulli type end effector that is configured to support a wafer in a non-contact manner according to the Bernoulli principle or effect in the manner described above.

Therefore, the end effector 29 comprises a plurality of gas channels having outlets 35 formed in a support surface 37 of each of the forks, fingers, prongs or blades 33. The gas channels are each angled outwards away from a centre of the end effector 29 in running towards the support surface 37, so that gas exits the outlets 35 in an outwards direction at an angle to the support surface 37 of >0° and <90°.

The end effector 29 further comprises a gas supply that is connected to each of the gas channels. For example, the gas supply may comprise a gas supply pipe. The gas supply may further comprise a gas distribution chamber that is connected to each of the gas channels.

The end effector 29 may be configured to support a wafer from above the wafer according to the Bernoulli principle or effect. The outlets 35 may therefore be formed on a lower or bottom surface of the end effector 29.

The end effector 29 is configured to be at least partly insertable into the grooves 27 of the plate 13. For example, at least part of the forks, fingers, prongs or blades 33 of the end effector 29 can be laterally inserted into the grooves 27 of the plate 13.

A depth of the grooves 27 of the plate 13 is greater than a thickness of the forks, fingers, prongs or blades 33 of the end effector 29. Therefore, a full thickness of the forks, fingers, prongs or blades 33 can be received in the grooves 27.

Therefore, the forks, fingers, prongs or blades 33 of the end effector 29 can be inserted into the grooves 27 of the plate 13 laterally (i.e. from the side of the plate 13 in a sideways direction) while a wafer is supported by the plate 13.

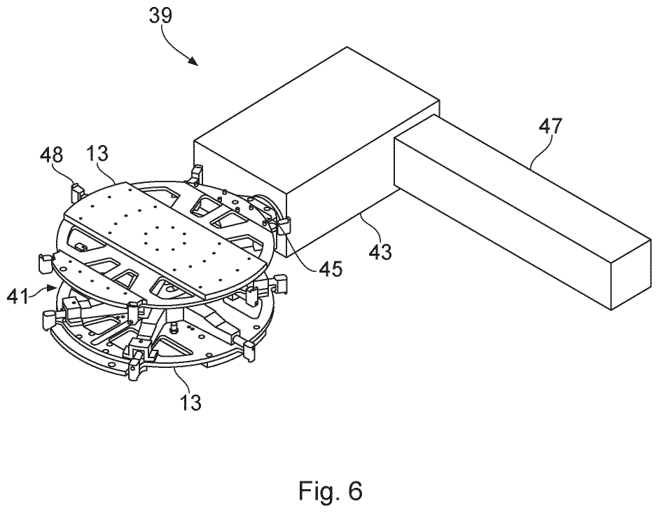

FIG. 6 is a schematic illustration of a device according to an embodiment of the present invention that includes the plate 13 of the first embodiment. In particular, FIG. 6 is a schematic illustration of a wafer conveying device 39 that includes the plate 13 described above.

As illustrated in FIG. 6, the device 39 includes two of the plates 13 according to the first embodiment of the present invention. The two plates 13 are arranged one above the other, with the support surfaces 15 of the plates 13 facing in opposite directions (away from each other). Therefore, when the support surface 15 of one of the plates 13 is facing upwards, the support surface 15 of the other plate 13 is facing downwards. Each of the plates 13 forms a respective support for supporting a wafer. The device 39 therefore comprises two supports for supporting a wafer.

Of course, in other embodiments the device 39 may comprise only a single one of the plates 13, and it is not essential for there to be more than one support as illustrated in FIG. 6.

The two support plates are connected together to form a unit 41, and the unit 41 is rotatably connected to an arm 43 of the device 39 by a rotary connection 45. The unit 41 can be rotated using the rotary connection 45 so as to flip the unit 41. When flipped, the support surface 15 that was facing upwards will then be facing downwards, and the support surface 15 that was facing downwards will then be facing upwards. For example, the unit 41 may be rotatable between a first configuration in which the support surface 15 of a first one of the plates 13 is facing upwards and a support surface 15 of a second one of the plates 13 is facing downwards, and a second configuration in which the support surface 15 of the first one of the plates 13 is facing downwards and the support surface 15 of the second one of the plates 13 is facing upwards.

The arm 43 is pivotably or rotatably connected to a linear movement mechanism 47 so that the arm 43 can be pivoted or rotated relative to the linear movement mechanism. For example. the arm 43 may be pivotable or rotatable between a first configuration in which the arm 43 is horizontal or substantially horizontal and a second configuration in which the arm 43 is vertical or substantially vertical.

The linear movement mechanism may be operable to move the arm 43 linearly, for example in a direction perpendicular to the arm 43. For example, the linear movement mechanism 47 may be a linear actuator.

Each of the plates 13 may have any of the features of the plate 13 described above and/or illustrated in FIGS. 1 to 4. These features are not individually numbered in FIG. 6 or repeated here for clarity and conciseness.

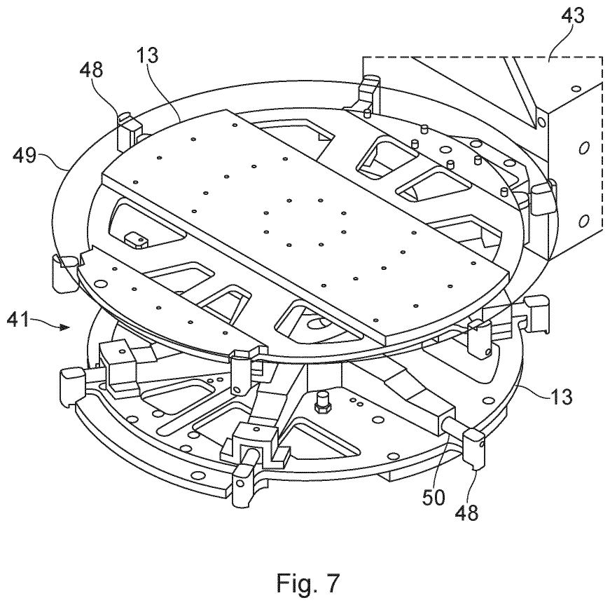

FIG. 7 is an enlarged view of the unit 41 showing a wafer 49 received by the upper one of the plates 13.

In operation, an end effector that supports a wafer from above according to the Bernoulli effect can be used to position the wafer on either of the two plates 13. For example, the end effector can be positioned above the upper one of the two plates 13 with the wafer between the end effector and the upper plate 13. Support of the wafer can then be transferred from the end effector to the upper plate 13, and the end effector and/or the unit 41 can then be moved away. For example, a supply of gas to the outlets of the end effector may be stopped and a flow of gas to the openings 19 of the upper plate may be started to transfer support of the wafer to the upper plate 13.

Alternatively, the end effector can be positioned below the lower one of the plates 13 with the end effector between the wafer and the lower plate 13. The end effector can be moved perpendicularly to the support surface 15 of the lower plate 13 so that at least part of the end effector is received in the grooves 17 in the support surface 15. Support of the wafer can then be transferred from the end effector to the lower plate 13. The end effector can then be laterally withdrawn from the grooves 17 in the support surface 15 while the wafer is supported by the lower plate 13.

When the wafer is positioned on the upper plate 13 in the manner described above, a first main face of the wafer faces away from the upper plate 13. When the unit 41 is subsequently flipped and the wafer is positioned on a rotary chuck of a wafer processing apparatus, a second main face of the wafer will face upwards and be exposed for processing.

In contrast, when the wafer is positioned on the lower plate 13 in the manner described above, a second main surface of the wafer faces away from the lower plate 13. When the wafer is subsequently positioned on a rotary chuck of a wafer processing apparatus, the first main face of the wafer will face upwards and be exposed for processing.

Therefore, with the present invention the wafer can be positioned on the rotary chuck of the wafer processing apparatus with either main face of the wafer exposed for processing, allowing either main face to be processed, or for both main faces to be processed sequentially.

In an alternative embodiment there may be only a single one of the plates 13 (or supports). The single one of the plates 13 may be flipped so as to position the support surface of the plate 13 facing upwards or facing downwards. Therefore, it is not essential for there to be more than one plate 13 as illustrated in FIGS. 6 and 7.

In a further alternative embodiment, the plate or plates 13 may not be flipable or rotatable. Instead, the end effector may be flipable or rotatable. Therefore, it is not essential for the plate or plates 13 to be flipable or rotatable as illustrated in FIGS. 6 and 7.

In addition, or alternatively, in other embodiments the support may not be in the form of a plate as illustrated in FIGS. 1 to 3. Instead, the support may comprise a body, which is not plate-like, that has the support surface and other features described above.

As illustrated in FIGS. 6 and 7, each of the plates 13 comprises a plurality of limiting elements 48 configured to limit lateral movement of a wafer being conveyed by the plate 13 relative to the support surface 15 of the plate 13.

In particular, each of the limiting elements 48 comprises a respective pin that protrudes from the plate 13 beyond the support surface 15 of the plate 13. Each of the pins is on a respective linearly extendable arm 50 that extends in a radial direction of the plate so that a radial position of the pin can be adjusted.

The plurality of pins are positioned around the circumference of the support surface 15 so as to contact an outer radial edge of a wafer supported by the support if the wafer is laterally displaced relative to the support surface 15. The plurality of pins therefore limit or restrict lateral movement of the wafer relative to the support surface. However, the plurality of pins do not grip the wafer.

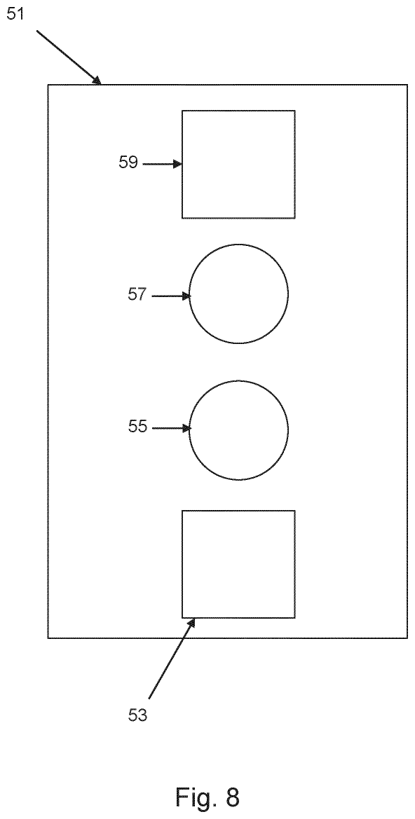

FIG. 8 is a schematic view of an apparatus according to an embodiment of the present invention. The apparatus 51 comprises a support 53 for supporting a wafer cassette that contains a plurality of wafers. The apparatus 51 further comprises a robotic arm 55 having an end effector which may have any of the features of the robotic arm and end effector described above. The robotic arm is configured to pick up a wafer from the wafer cassette using the end effector.

In addition, the apparatus 51 further comprises a wafer conveying device 57 which may have any of the features of the wafer conveying device described above. The robotic arm 55 transports a wafer picked up from the wafer cassette to the wafer conveying device 57. Support of the wafer is then transferred from the end effector to the wafer conveying device 57.

In addition, the apparatus 51 further comprises a wafer processing apparatus 59. For example, the wafer processing apparatus may comprise a spin etching or spin cleaning apparatus. The wafer processing apparatus 59 may comprise a wafer support such as a rotary chuck for receiving and supporting the wafer from the wafer conveying device 57. The wafer processing apparatus 59 may further comprise a liquid dispenser for dispensing a processing liquid onto an upper surface of the wafer supported by the wafer support.

The device 39 further comprises a controller, for example a microprocessor, for controlling an operation of the device 39. For example, the controller may control the supply of gas to the gas channels of the plate or plates 13 to control picking up, conveying, and putting down of the wafer by the support.

Of course, in other embodiments the configuration of the end effector may be different to that illustrated in FIG. 5, and the number and/or configuration of the grooves in the support surface may therefore also be different. For example, the end effector may have no forks, fingers, prongs or blades, or one or more forks, fingers, prongs or blades, and the support surface may have a corresponding number of one or more grooves.

Furthermore, the number and/or arrangement of the gas channels and outlets may be different to that illustrated in FIGS. 1 to 4.

In other embodiments of the invention, the support surface and channel may be formed in a support of a device for conveying a wafer, rather than in the plate of the first embodiment of the present invention. For example, the support may be a one piece support having the support surface and grooves.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

1. A device for conveying a wafer-shaped article, comprising:
a support having a support surface;
one or more gas channels in the support having one or more outlets in the support surface; and
one or more grooves in the support surface for receiving at least part of an end effector for supporting a wafer-shaped article.

2. The device according to claim 1, wherein the device further comprises a plurality of limiting elements configured to limit lateral movement of a wafer-shaped article being conveyed by the device relative to the support surface.

3. The device according to claim 1, wherein the one or more gas channels are configured to supply gas to support a wafer-shaped article according to the Bernoulli principle.

4. The device according to claim 1, wherein the one or more gas channels are configured to supply gas to support a wafer-shaped article in a non-contact manner.

5. The device according to claim 1, where the device comprises a plurality of the gas channels in the support, each having a respective outlet in the support surface.

6. The device according to claim 1, wherein the one or more gas channels are each angled outwards relative to the support surface.

7. The device according to claim 1, wherein the one or more gas channels are each at an angle of >0° and <90° to the support surface.

8. The device according to claim 1, wherein the one or more grooves are each linear or substantially linear.

9. The device according to claim 1, wherein the device comprises two or more of the grooves.

10. The device according to claim 1, wherein each of the one or more grooves extends to an edge of the support surface.

11. The device according to claim 1, wherein the device comprises one or more openings or cut-outs in the one or more grooves.

12. The device according to claim 1, wherein the device comprises a gas distribution chamber in the support, wherein each of the one or more gas channels is connected to the gas distribution chamber.

13. The device according to claim 1, wherein the support surface is on an underside of the device when the device is used to convey a wafer-shaped article.

14. The device according to claim 1, wherein the device is configured to support a wafer-shaped article from above the wafer-shaped article.

15. The device according to claim 1, wherein the device comprises a rotation mechanism for flipping the support.

16. The device according to claim 1, wherein the device comprises two supports arranged with their support surfaces facing in opposite directions, or substantially opposite directions.

17. A plate for use in a device for conveying a wafer-shaped article, comprising:
a support surface;
one or more gas channels in the plate having one or more outlets in the support surface; and
one or more grooves in the support surface for receiving at least part of an end effector for supporting a wafer-shaped article.

18. A support for use in a device for conveying a wafer-shaped article, comprising:
a support surface;
one or more gas channels in the support having one or more outlets in the support surface; and
one or more grooves in the support surface for receiving at least part of an end effector for supporting a wafer-shaped article.

19. A device for conveying a wafer-shaped article, comprising a plate according to claim 17.

20. An apparatus comprising:
a device according to claim 1; and
a robotic arm having an end effector;
wherein the end effector is configured to be at least partly insertable into the one or more grooves in the support surface of the device.

21. The apparatus according to claim 20, wherein the end effector is a Bernoulli type end effector.

22. The apparatus according to claim 20, wherein the end effector comprises a support surface having one or more gas outlets.

23. A device for conveying a wafer-shaped article, comprising a support according to claim 18.
